(19) United States
(12) Patent Application Publication
(10) Pub. No.: US 2025/0167058 A1
(43) Pub. Date: May 22, 2025

(54) ENHANCHED THERMAL DISSIPATION IN FLIP-CHIP SEMICONDUCTOR DEVICES USING LASER DIRECT (LDS) STRUCTURING TECHNOLOGY

(71) Applicant: STMicroelectronics S.r.l., Agrate Brianza (MB) (IT)

(72) Inventors: Michele DERAI, Milano (IT); Dario VITELLO, Merate (LC) (IT)

(73) Assignee: STMicroelectronics S.r.l., Agrate Brianza (MB) (IT)

(21) Appl. No.: 19/032,932

(22) Filed: Jan. 21, 2025

Related U.S. Application Data
(62) Division of application No. 17/549,058, filed on Dec. 13, 2021, now Pat. No. 12,211,763.

(30) Foreign Application Priority Data
Dec. 17, 2020 (IT) 102020000031244

(51) Int. Cl. H01L 23/29; H01L 21/48; H01L 23/31; H01L 23/495

(52) U.S. Cl. CPC H01L 23/29; H01L 21/4821; H01L 23/31; H01L 23/495

(57) ABSTRACT

A device includes a leadframe with a semiconductor die having a first side facing and electrically coupled to the leadframe and a second side facing away from the leadframe. An encapsulation body containing laser direct structuring (LDS) material covers the semiconductor die and has an outer surface opposite the leadframe. Metal vias are formed through the LDS material between the outer surface and the second side of the semiconductor die, and a metal pad is formed at the outer surface. The metal vias and pad create a thermal dissipation path. The semiconductor die may be mounted in a flip-chip configuration and connected to the leadframe through metal pillars. The metal vias and pad may be formed by laser-activating the LDS material followed by copper plating. The device can be configured as a Quad Flat No-leads (QFN) package, and a heat sink may be mounted on the metal pad.

### PRIORITY CLAIM

This application is a division of U.S. application patent Ser. No. 17/549,058, filed Dec. 13, 2021, which itself claims the priority benefit of Italian Application for Patent No. 102020000031244, filed on Dec. 17, 2020, the contents of which are hereby incorporated by reference in their entireties to the maximum extent allowable by law.

### TECHNICAL FIELD

The description relates to semiconductor devices. In particular, one or more embodiments may be applied to semiconductor devices such as integrated circuits (ICs).

### BACKGROUND

Semiconductor devices such as, for instance, Quad Flat No-leads (QFN) packages having peripheral lands at the package bottom in order to provide electrical connection via flip-chip mounting on a substrate, such as a printed circuit board (PCB), stimulate an ever-increasing interest for various applications.

Good heat dissipation facilitates adequate performance of these devices. An exposed pad is now conventionally used in standard QFN packages in order to increase thermal dissipation.

However, it is observed that such an approach may suffer from various reliability issues related to power dissipation. This is found to be particularly the case for flip-chip type semiconductor devices.

There is a need in the art to contribute in providing improved approaches overcoming these drawbacks.

### SUMMARY

One or more embodiments may relate to a method.

One or more embodiments may relate to a corresponding semiconductor device.

One or more embodiments involve molding a die/dice and a leadframe in the device with laser-direct-structuring (LDS) material (a molding compound with a chromium oxide particle filler, for instance).

One or more embodiments benefit from the proven capability of laser-direct-structuring (LDS) technology to form vias and tracks.

One or more embodiments may exhibit detectable metal (e.g., copper) filled vias and a heat spreader molding compound (with chromium oxide particles).

One or more embodiments may facilitate high thermal dissipation from semiconductor devices, possibly via dual-side dissipation.

One or more embodiments are compatible for use in those devices that benefit from good thermal dissipation, for instance in a flip-chip version.

For instance, this may be the case in power devices where full exploitation of package leads as input/output (I/O) nodes is a desirable feature, with heat dissipation entrusted primarily to backside semiconductor material (silicon) through a top exposed pad.

One or more embodiments benefit from a top thermal pad created through LDS activation and metal (e.g., Cu) plating, which provides improved thermal dissipation in comparison with standard flip-chip solutions.

Also disclosed herein is a device that includes a leadframe and at least one semiconductor die arranged on the leadframe. The semiconductor die has a first side facing towards the leadframe and electrically coupled therewith, and a second side facing away from the leadframe. An encapsulation body is on the at least one semiconductor die, wherein the encapsulation body has an outer surface opposite the leadframe and includes laser direct structuring (LDS) material. At least one metal via is formed in the LDS material of the encapsulation body between the outer surface of the encapsulation body and the second side of the at least one semiconductor die. A metal pad is formed at the outer surface of the LDS material of the encapsulation body.

The device may include a metallization at the second side of the at least one semiconductor die, where the at least one metal via can be coupled to the metallization. The device may include at least one additional metal via formed in the LDS material of the encapsulation body between the outer surface of the encapsulation body and the leadframe.

The device may include a plating portion of the leadframe configured such that the at least one additional metal via enables plating growth of the metal pad at the outer surface of the encapsulation body. The device may include metal material in at least one laser-activated hole drilled in the LDS material of the encapsulation body to provide the at least one metal via between the outer surface of the encapsulation body and the second side of the at least one semiconductor die, and metal material at the outer surface of the LDS material of the encapsulation body to provide the metal pad.

The device may include metal pillars electrically coupling the first side of the at least one semiconductor die with the leadframe. A heat sink may be mounted on the metal pad at the outer surface of the encapsulation body. The LDS material may include a thermoplastic material doped with a laser-activatable compound that forms electrically conductive formations.

The metal pad and the at least one metal via may include copper formed by electroless plating and galvanic plating. The copper may be plated with layers of nickel and gold. The leadframe may include a pre-molded leadframe having an insulating compound molded on a metal structure.

The at least one semiconductor die may be mounted in a flip-chip configuration with its bottom side facing upward and its front side facing downward toward the leadframe. The at least one metal via may provide both electrical and thermal conductivity between the metal pad and the second side of the at least one semiconductor die. The leadframe may include a plated bottom surface.

The device may be configured in a Quad Flat No-leads (QFN) package configuration. The at least one metal via and the metal pad may form a thermal dissipation path from the second side of the at least one semiconductor die to the outer surface of the encapsulation body.

In another implementation, a device includes a leadframe and a semiconductor die mounted in a flip-chip configuration on the leadframe, wherein the semiconductor die has a metallized back surface facing away from the leadframe. A plurality of metal pillars electrically couple a front surface of the semiconductor die to the leadframe. An encapsulation body includes laser direct structuring (LDS) material covering the semiconductor die and at least a portion of the leadframe. A plurality of metal-filled vias extend through the encapsulation body to the metallized back surface of the semiconductor die. A thermal pad is formed on an outer surface of the encapsulation body and connected to the plurality of metal-filled vias.

The thermal pad may include electroless-plated copper. The leadframe may include a pre-plated leadframe having an insulating compound molded on a metal structure. The device may include at least one connection via extending through the encapsulation body between the thermal pad and the leadframe, wherein the at least one connection via enables electroplating growth of the thermal pad. The plurality of metal-filled vias and the thermal pad may be formed from laser-activated portions of the LDS material that have been metallized.

### BRIEF DESCRIPTION OF THE DRAWINGS

One or more embodiments will now be described, by way of example only, with reference to the annexed figures, wherein:

FIG. 1 is a cross-sectional view of a semiconductor device as per embodiments of the present description;

FIG. 1A is a cross-sectional view of a semiconductor device as per embodiments of the present description;

FIGS. 2 and 3 are cross-sectional views of a semiconductor device illustrative of possible options in implementing embodiments of the present description; and

FIGS. 4A to 4G are illustrative of a possible assembly flow in forming embodiments of the present description.

It will be appreciated that, for the sake of clarity and ease of understanding, the various figures may not be drawn to a same scale.

### DETAILED DESCRIPTION

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular conformations, structures, or characteristics may be combined in any adequate way in one or more embodiments.

The headings/references used herein are provided merely for convenience and hence do not define the extent of protection or the scope of the embodiments.

Also, throughout the figures, unless the context indicates otherwise, like parts or elements are indicated with like reference symbols, and a corresponding description will not be repeated for each and every figure for brevity.

Various types of conventional semiconductor devices comprise a leadframe on which one or more semiconductor chips or dice are mounted.

The designation leadframe (or lead frame) is currently used to indicate a metal frame which provides support for a semiconductor chip or die as well as electrical leads to couple the semiconductor chip or die to other electrical components or contacts.

Essentially, a leadframe comprises an array of electrically-conductive formations (leads) which from a peripheral location extend inwardly in the direction of the semiconductor chip or die, thus forming an array of electrically-conductive formations from the die pad having at least one semiconductor chip or die attached thereon. This may be via a die attach adhesive (a die-attach film or DAF, for instance).

Electrical coupling of the leads in the lead frame with the semiconductor chip or die may be via wires forming a wire-bonding pattern around the chip or die.

The device package is completed by an insulating encapsulation formed by molding a compound such as an epoxy resin on the leadframe and the semiconductor chip(s) attached thereon.

Semiconductor devices of the Quad Flat No-leads (QFN) type may resort to a ball-grid array (BGA) for electrical connection to external circuitry (a printed circuit board or PCB, for instance), The resulting arrangement is referred to as a QFN/BGA arrangement.

In conventional QFN/BGA arrangements, where semiconductor chip(s) mounted on a leadframe have pads at their top or front surface connected to the leadframe via a wire bonding pattern, an exposed die pad can be provided in order to facilitate thermal dissipation.

Semiconductor devices of the so-called flip-chip type include interconnections to external circuitry via solder bumps deposited on chip pads formed at the top or front side of the semiconductor chip or die. The chip is coupled to external circuitry (a printed circuit board or PCB, for instance) by flipping it over so that its front side faces downwards. The pads at that surface are aligned with corresponding pads on the external circuit (PCB, for instance). Solder reflow completes the interconnection.

As a result, in conventional semiconductor devices of the flip-chip type (which may otherwise adopt a QFN/BGA configuration) the semiconductor chips are usually mounted in the package turned upside down (bottom side up and top side down). Thermal dissipation from the device is inevitably poor insofar as bottom or back side of the die or chip is not in contact with a metal plate, with heat dissipation occurring only through metal (e.g., Cu) pillars, with the die area coupled to the leadframe for heat transfer being small so the thermal dissipation performance of the device is poor.

For that reason, flip-chip packages are used primarily for devices with (very) low thermal dissipation being expected and/or those applications where reduced thermal dissipation in not regarded as a critical feature.

One or more embodiments may take advantage from laser direct structuring technology applied to manufacturing semiconductor devices.

Laser direct structuring (LDS) is a technology adopted in various areas which may involve molding (injection molding, for instance) of resins containing additives.

A laser beam can be applied to the surface of a molded part in order to transfer thereto a desired pattern. A metallization process such as an electro-less plating process, involving metals such as copper can then be used to plate a desired conductive pattern on the laser-activated surface. LDS processing is also known to be suited for providing vias or contact pads.

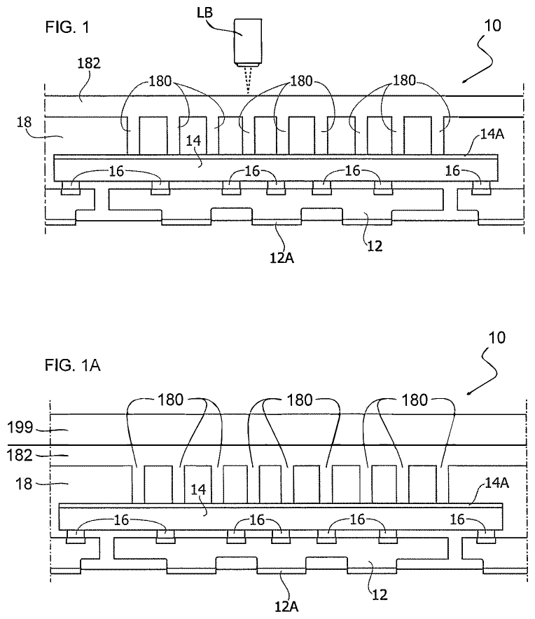

FIG. 1 is illustrative of semiconductor device 10 which can be manufactured in accordance with embodiments as described herein.

As otherwise conventional in the art, a device such as the semiconductor device 10 can be manufactured as a part of an array (a string or strip, for instance) of similar devices which are finally separated via “singulation”. The figures are illustrative of steps applied in order to produce one such device. It will be otherwise understood that these steps can be applied to fabricating plural devices 10 simultaneously.

A semiconductor device 10 as illustrated in FIG. 1 comprises a leadframe 12 on which one or more semiconductor chips or dice 14 are mounted: a single chip or die 14 is illustrated here for simplicity.

The leadframe 12 may be of the pre-molded type with an insulating compound molded on a basic metal structure of the leadframe etched out of a metal (e.g., copper) strip or reel.

The leadframe 12 may be plated at its bottom or back surface as shown at 12A.

Mounting of the chip or die 14 on the leadframe 12 may be via bumps 16, with the chip or die turned upside down (referred to in the art as “flip-chip”), that is with its bottom or back side (possibly metallized at 14A) facing upwards and its top or front side facing downwards.

An encapsulation 18 can be molded on the leadframe 12 and the semiconductor chip(s) 14 attached thereon.

In one or more embodiments, the encapsulation 18 is provided using laser direct structuring (LDS) material.

This material may include, for instance, a thermoplastic material, doped with a compound which can be activated by a laser. Subsequent metallization, for instance in an electroless copper bath with layers of copper, nickel, and gold finish formed thereon facilitates providing electrically-conductive formations at the locations where the LDS material was laser-activated. LDS technology has proved to be suited for use in providing vias or contact pads.

FIG. 1 is illustrative of a device 10 where an LDS molding compound 18 can be molded on a die 14 with backside metallization 14A.

Laser beam energy as exemplified at LB and LDS processing can be applied to form one or more (electrically-and thermally-conductive) metallized vias 180 extending through the molding compound down to the (bottom or back metallization 14A of the) die 14 and to structure a thermal pad 182 on the top of the package of the device 10.

For instance, electroless plating and galvanic Cu plating facilitate growing a thermal pad 182 on top of the package, creating a connection with external world for thermal dissipation. For instance, an additional heat sink (shown in FIG. 1A) can be added on top of the thermal pad 182.

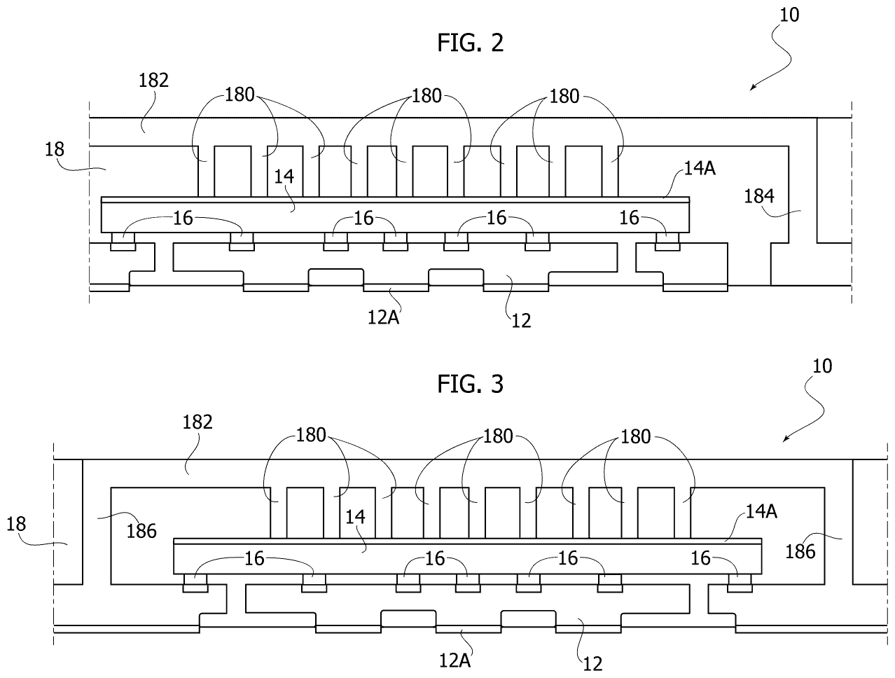

FIGS. 2 and 3 are illustrative of different options in implementing an arrangement as illustrated in FIG. 1.

Unless the context indicates otherwise, in FIGS. 2 and 3 parts or elements like parts or elements already discussed in connection with FIG. 1 are indicated with like reference symbols so that a corresponding description will not be repeated for brevity.

As illustrated in FIG. 2, a sacrificial via 184 (to be removed during a final singulation step) can be provided on external rail to allow current continuity to the top exposed pad 182 and a thick copper growth on top of the thermal pad 182.

As illustrated in FIG. 3, some leads in the leadframe 12 can be used to connect through vias 186 the top exposed pad 182 again allowing thick copper growth on top of the thermal pad 182.

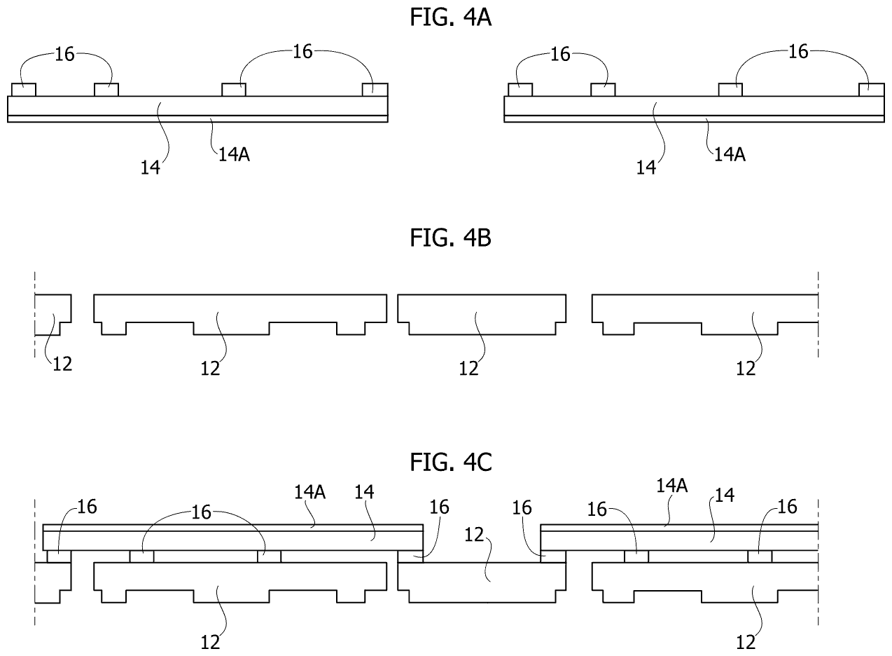

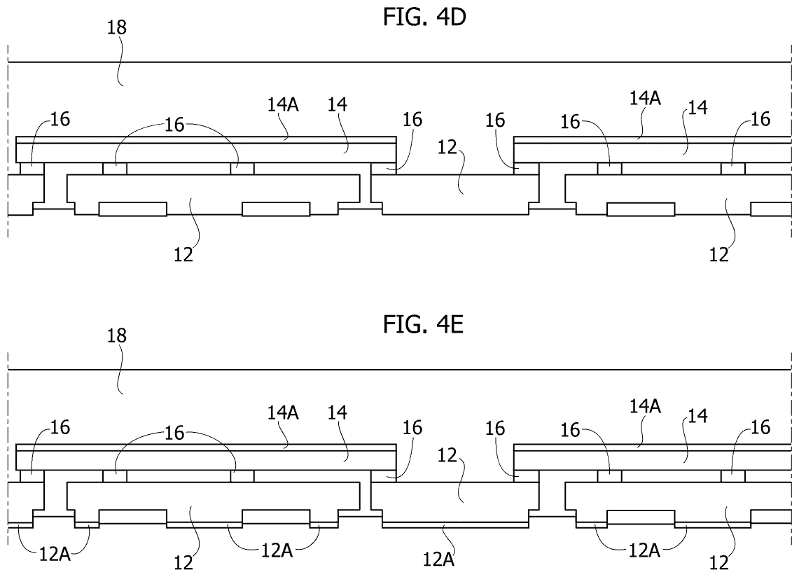

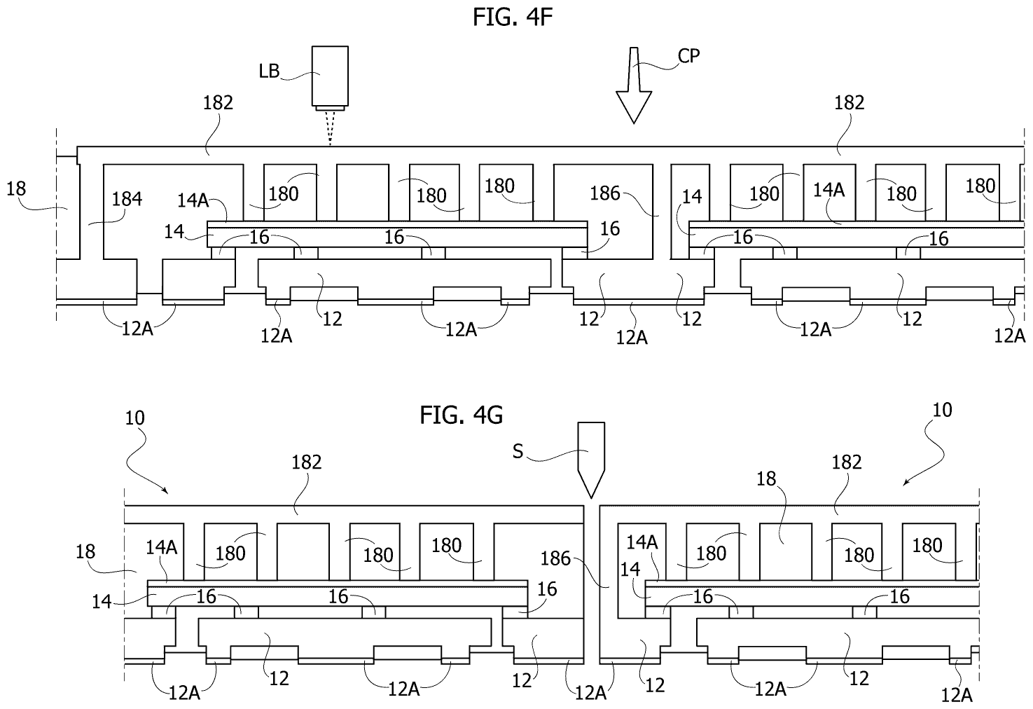

FIGS. 4A to 4G are illustrative of a possible assembly flow in embodiments of the present description.

Those of skill in the art will otherwise appreciate that certain steps as exemplified in FIGS. 4A to 4G may be omitted or replaced by other steps or other steps may be added. Also, one or more steps in the process may be performed in an order different from the order exemplified in FIGS. 4A to 4G.

FIG. 4A is exemplary of pillars 16 (e.g., copper) being grown on (the front or top surface of) semiconductor chips or dice 14 metallized at 14A at their bottom or back side.

FIG. 4B is exemplary of a leadframe 12 being provided on which the semiconductor chips or dice 14 are attached (turned upside down) as exemplified in FIG. 4C.

FIG. 4D is exemplary of a step where (for instance after reflow and flux cleaning) a LDS molding compound 18—that is, a molding compound comprising laser-activatable material as used in LDS technology—is molded on the structure illustrated in FIG. 4C.

These steps can be performed in any suitable way, as will be appreciated by those of skill in the art.

After possible plating (e.g., tin plating) at 12A as illustrated in FIG. 4E (if no pre-plated LF is available), LDS processing is applied to the molding compound 18 as illustrated in FIG. 4F.

As illustrated in FIG. 4F, LDS processing of the molding compound 18 may comprise laser activation as exemplified at LB and metallization (electroless and galvanic Cu plating for instance) in order to form the vias 180 and the exposed pad 182.

Merely by way of illustration, FIG. 4F (and FIG. 4G) represent: on the left side of the figure, the option illustrated in FIG. 2 (sacrificial vias 184 to be removed during a the final singulation step of FIG. 4G), and on the right side of the figure, the option illustrated in FIG. 3 (leads in the leadframe 12 used to connect through vias 186 the top exposed pad 182).

As noted, such a representation is merely by way of illustration, in so far as industrial assembly flows implemented on a certain strip of devices will expectedly apply either of these options.

FIG. 4G is exemplary of a final singulation step, performed in a conventional way via a sawing tool S, for instance, in order to partition such a strip into individual semiconductor devices 10.

Briefly, a method as exemplified herein may comprise: arranging on a leadframe (for instance, 12) at least one semiconductor chip or die (for instance, 14) having a first side facing towards the leadframe and electrically coupled therewith (for instance, via metal, e.g., copper pillars 16) and a second side facing away from the leadframe; molding an (insulating) encapsulation (for instance, 18) on the at least one semiconductor chip or die arranged on the leadframe, wherein the encapsulation has an outer surface opposite the leadframe and comprises laser direct structuring, LDS material; and applying laser direct structuring processing (for instance, LB, CP) to the LDS material of the encapsulation to provide at least one metal via (for instance, 180) between the outer surface of the encapsulation and the second side of the at least one semiconductor chip or die, and a metal pad (for instance, 182) at the outer surface of the encapsulation.

In a method as exemplified herein, laser direct structuring processing applied to the LDS material of the encapsulation may comprise: applying laser beam energy (for instance, LB) to the outer surface of the encapsulation in order to drill at least one laser-activated hole between the outer surface of the encapsulation and the second side of the at least one semiconductor chip or die and to provide laser activation of the outer surface of the encapsulation, and growing (for instance, CP) metal material in the at least one laser-activated hole to provide said at least one metal via between the outer surface of the encapsulation and the second side of the at least one semiconductor chip or die, and at the outer surface of the encapsulation to provide said metal pad at the outer surface of the encapsulation.

A method as exemplified herein may comprise forming a metallization (for instance, 14A) at the second side of the at least one semiconductor chip or die wherein the at least one metal via is (electrically and/or thermally) coupled to said metallization.

A method as exemplified herein may comprise electrically coupling the first side of the at least one semiconductor chip or die with the leadframe via metal pillars (for instance, 16).

A method as exemplified herein may comprise: applying laser direct structuring processing (LB, CP) to the LDS material of the encapsulation to provide at least one metal via (for instance, 184, 186) between the outer surface of the encapsulation and the leadframe, wherein said at least one metal via facilitates forming said metal pad at the outer surface of the encapsulation.

A method as exemplified herein may comprise: applying laser direct structuring processing to the LDS material of the encapsulation to provide at least one sacrificial metal via (for instance, 184) between the outer surface of the encapsulation and the leadframe, wherein the at least one sacrificial metal via facilitates forming said metal pad at the outer surface of the encapsulation, and removing (for instance, S) the at least one sacrificial metal via following formation of said metal pad at the outer surface of the encapsulation.

A device (for instance, 10) as exemplified herein may comprise: a leadframe (for instance, 12) having arranged thereon at least one semiconductor chip or die (for instance, 14) having a first side facing towards the leadframe and electrically coupled therewith (for instance, via pillars such as 16) and a second side facing away from the leadframe; an encapsulation (for instance, 18) molded on the at least one semiconductor chip or die arranged on the leadframe, wherein the encapsulation has an outer surface opposite the leadframe and comprises laser direct structuring, LDS material; at least one metal via (for instance, 180) formed in the LDS material of the encapsulation between the outer surface of the encapsulation and the second side of the at least one semiconductor chip or die; and a metal pad (for instance, 182) formed at the outer surface of the LDS material of the encapsulation.

A device as exemplified herein may comprise metal material grown: in at least one laser-activated hole drilled in the LDS material of the encapsulation to provide said at least one metal via between the outer surface of the encapsulation and the second side of the at least one semiconductor chip or die; and at the outer surface of the LDS material of the encapsulation to provide said metal pad at the outer surface of the encapsulation.

A device as exemplified herein may comprise a metallization (for instance, 14A) at the second side of the at least one semiconductor chip or die, wherein the at least one metal via is coupled (electrically and/or thermally) to said metallization.

A device as exemplified herein may comprise metal pillars (for instance, 16) electrically coupling the first side of the at least one semiconductor chip or die with the leadframe.

A device as exemplified herein may comprise at least one metal via (for instance, 186) formed in the LDS material of the encapsulation between the outer surface of the encapsulation and the leadframe.

It will be appreciated that sacrificial vias such as 184 will no longer be visible in individual devices 10 after singulation (see S in FIG. 4G).

Without prejudice to the underlying principles, the details and the embodiments may vary, even significantly, with respect to what has been described by way of example only without departing from the scope of the embodiments.

1. A device, comprising:
a leadframe;
at least one semiconductor die arranged on the leadframe and having a first side facing towards the leadframe and electrically coupled therewith, and a second side facing away from the leadframe;
an encapsulation body on the at least one semiconductor die, wherein the encapsulation body has an outer surface opposite the leadframe and comprises laser direct structuring (LDS) material;
at least one metal via formed in the LDS material of the encapsulation body between the outer surface of the encapsulation body and the second side of the at least one semiconductor die; and
a metal pad formed at the outer surface of the LDS material of the encapsulation body.

2. The device of claim 1, further comprising a metallization at the second side of the at least one semiconductor die, wherein the at least one metal via is coupled to the metallization.

3. The device of claim 1, further comprising at least one additional metal via formed in the LDS material of the encapsulation body between the outer surface of the encapsulation body and the leadframe.

4. The device of claim 3, further comprising a plating portion of the leadframe configured such that the at least one additional metal via facilitates plating growth of the metal pad at the outer surface of the encapsulation body.

5. The device of claim 1, further comprising:
metal material in at least one laser-activated hole drilled in the LDS material of the encapsulation body to provide the at least one metal via between the outer surface of the encapsulation body and the second side of the at least one semiconductor die; and
metal material at the outer surface of the LDS material of the encapsulation body to provide the metal pad.

6. The device of claim 1, further comprising metal pillars electrically coupling the first side of the at least one semiconductor die with the leadframe.

7. The device of claim 1, further comprising a heat sink mounted on the metal pad at the outer surface of the encapsulation body.

8. The device of claim 1, wherein the LDS material comprises a thermoplastic material doped with a laser-activatable compound that forms electrically conductive formations.

9. The device of claim 1, wherein the metal pad and the at least one metal via comprise copper formed by electroless plating and galvanic plating.

10. The device of claim 9, wherein the copper is plated with layers of nickel and gold.

11. The device of claim 1, wherein the leadframe comprises a pre-molded leadframe having an insulating compound molded on a metal structure.

12. The device of claim 1, wherein the at least one semiconductor die is mounted in a flip-chip configuration with its bottom side facing upward and its front side facing downward toward the leadframe.

13. The device of claim 1, wherein the at least one metal via provides both electrical and thermal conductivity between the metal pad and the second side of the at least one semiconductor die.

14. The device of claim 1, wherein the leadframe comprises a plated bottom surface.

15. The device of claim 1, wherein the device is configured in a Quad Flat No-leads (QFN) package configuration.

16. The device of claim 1, wherein the at least one metal via and the metal pad form a thermal dissipation path from the second side of the at least one semiconductor die to the outer surface of the encapsulation body.

17. A device, comprising:
a leadframe;
a semiconductor die mounted in a flip-chip configuration on the leadframe, wherein the semiconductor die has a metallized back surface facing away from the leadframe;
a plurality of metal pillars electrically coupling a front surface of the semiconductor die to the leadframe;
an encapsulation body comprising laser direct structuring (LDS) material covering the semiconductor die and at least a portion of the leadframe;
a plurality of metal-filled vias extending through the encapsulation body to the metallized back surface of the semiconductor die; and
a thermal pad formed on an outer surface of the encapsulation body and connected to the plurality of metal-filled vias.

18. The device of claim 17, wherein the thermal pad comprises electroless-plated copper.

19. The device of claim 17, wherein the leadframe comprises a pre-plated leadframe having an insulating compound molded on a metal structure.

20. The device of claim 17, further comprising at least one connection via extending through the encapsulation body between the thermal pad and the leadframe, wherein the at least one connection via facilitates electroplating growth of the thermal pad.

21. The device of claim 17, wherein the plurality of metal-filled vias and the thermal pad are formed from laser-activated portions of the LDS material that have been metallized.
